(19) United States
(12) Patent Application Publication
(10) Pub. No.: US 2007/0161212 A1
(43) Pub. Date: Jul. 12, 2007

(54) METHOD FOR MANUFACTURING MOSFET ON SEMICONDUCTOR DEVICE

(76) Inventor: Young Seong Lee, Gyeonggi-di (KR)

Correspondence Address: SHERR & NOURSE, PLLC, 620 HERNDON PARKWAY, SUITE 200, HERNDON, VA, 20170, US

(21) Appl. No.: 11/616,274

(22) Filed: Dec. 26, 2006

(30) Foreign Application Priority Data
Dec. 27, 2005 (KR) 10-2005-0131008

(51) Int. Cl. H01L 21/326; H01L 21/479

(52) U.S. Cl. 438/467; 257/E23.149

(57) ABSTRACT

A method for manufacturing a semiconductor device having a fuse area and a pad area. An inter-layer dielectric layer is deposited over a semiconductor substrate having a metal interconnection. A protection layer is deposited over the inter-layer dielectric layer. A photoresist mask is used to define areas to be etched in the fuse area and a pad area. The protection layer and the inter-layer dielectric layer are etched in the pad area and the fuse area, thereby exposing the metal interconnection in the pad area, and removing the dielectric material to a predetermined depth in a fuse area, using an etching gas including a first component. The first etching process is stopped. A second etching process is performed for selectively etching a surface of the metal interconnection using an etching gas including a second component.

The present application claims priority under 35 U.S.C. 119 and 35 U.S.C. 365 to Korean Patent Application No. 10-2005-0131008 (filed on Dec. 27, 2005), which is hereby incorporated by reference in its entirety.

### BACKGROUND

Recently, with advances in semiconductor manufacturing technology and applications, interest has focused on increasing the scale of integration by miniaturizing semiconductor devices. In this effort, the line width of gate electrodes or a bit line of a MOSFET memory has gotten much smaller.

FIGS. 1A to 1D are sectional views showing a manufacturing process of a related metal-oxide-semiconductor field-effect transistor (MOSFET), particularly, processes for forming a gate insulating layer before forming a gate electrode.

As shown in FIGS. 1A to 1D, the gate insulating layer design of a logic product is divided into an input/output (I/O) power line area and a core power line area. The gate insulating layer has dual thicknesses corresponding to differing operational voltages.

As shown in FIG. 1A, an isolation process is performed on a silicon semiconductor substrate 100, thereby forming an isolation layer 102 dividing an active region and an isolation region. Then, an ion implantation process is performed with respect to the entire surface of the semiconductor substrate 100, thereby forming a well. A first oxide layer 104 is grown to form the gate insulating layer.

Thereafter, as shown in FIG. 1B, the I/O power line area is masked, so that the oxide layer of the core power line area is removed through a wet etching scheme.

Referring to FIG. 1C, a thin second oxide layer 106 is grown over the core power line area. The second oxide layer 106 is also grown over the first oxide layer 104, so the I/O power line area has, in aggregate, a thicker oxide layer.

Referring to FIG. 1D, a nitrogen annealing process is performed over the resultant structure, forming a nitride-rich gate oxide layer on an interfacial surface of the active area. With this structure, N trapping may occur at the interface between two oxide layers of the I/O power line area. The probability of N trapping increases with increasing thickness of the first oxide layer 104. If a sufficient Si—N bond is not formed near the surface of the active area, stress may build at the interface. This can cause degradation of the electrical properties of the transistor.

To form a gate electrode, a doped polysilicon layer is deposited, patterned, and etched. Then, a MOSFET is formed through a series of processes, including forming a lightly doped drain area, a spacer, and a source/drain (S/D) area.

When the MOSFET is exposed to intense plasma during a subsequent dry etching process in a back end of line (BEOL), due to the N trapping, the MOSFET generates static charges by generating holes. Generally, to prevent the phenomenon, the gate electrode is grounded to an active area to distribute the static charges, while electrical arcing (plasma producing shocks) is generally minimized through the control of conditions in a manufacturing process. However, design capacities for shock distribution from static electricity may be restricted, and may also be difficult to set manufacturing conditions to reduce electrical arcing, so that the degradation of the transistor becomes difficult to avoid.

In particular, unlike other processes of BEOL, since a pad exposure process shown in FIGS. 2A and 2B is performed after completing the interconnection, an electric shock delivered directly to the device through the pad may cause the degradation of the device. A pMOS transistor, particularly, is more weakened by the shock of positive ions generated during the manufacturing process.

Although it is easy to prevent device degradation through better plasma control during a single pad exposure process, if the etching process of an oxide layer 204 includes the fuse area and the pad area, which is performed to simplify a masking step, it is more difficult to set manufacturing conditions. This is because the thickness control of a fuse oxide layer and the pad area must be simultaneously considered.

In detail, when a metal pad having an upper TiN structure is exposed, the TiN is completely removed so that aluminum 202, which is an upper metal interconnection, can be exposed. The thickness of the oxide layer 204 of the fuse area is etched to a predetermined level. A reactive ion etching (RIE) process using fluorine (F) as a reactive ion selectively etches relative to an insulating layer. TiN is controlled to a low level so that the thickness of the oxide layer 204 can be controlled. To this end, the pressure in the chamber is maintained as low as possible.

However, as the chamber pressure is lowered, the strength of plasma increases, so device characteristics are degraded by the generation of static electricity.

The degradation of the pMOS transistor by the pad exposure process increases the threshold voltage, decreases a saturation current, and increases an off leakage current as shown in FIG. 3.

### SUMMARY

Embodiments relate to a method for manufacturing a MOSFET of a semiconductor device which prevents the MOSFET from being degraded by changing etching conditions to remove material remaining from an upper part of a metal interconnection when uncovering a pad on the MOSFET.

Embodiments relate to a method for manufacturing a semiconductor device having a fuse area and a pad area. An inter-layer dielectric layer is deposited over a semiconductor substrate having a metal interconnection. A protection layer is deposited over the inter-layer dielectric layer. A photoresist mask is used to define areas to be etched in the fuse area and a pad area. The protection layer and the inter-layer dielectric layer are etched in the pad area and the fuse area, thereby exposing the metal interconnection in the pad area, and removing the dielectric material to a predetermined depth in a fuse area, using an etching gas including a first component. The first etching process is stopped. A second etching process is performed for selectively etching a surface of the metal interconnection using an etching gas including a second component. The first component may be fluorine (F), and the second component may be chlorine (Cl) gas.

### BRIEF DESCRIPTION OF THE DRAWINGS

FIGS. 1A to 1D are section views sequentially showing processes for forming a gate insulating layer of a related semiconductor device;

FIGS. 2A and 2B are sectional views showing a method for manufacturing a related MOSFET;

FIG. 3 is a sectional view showing a related MOSFET; and

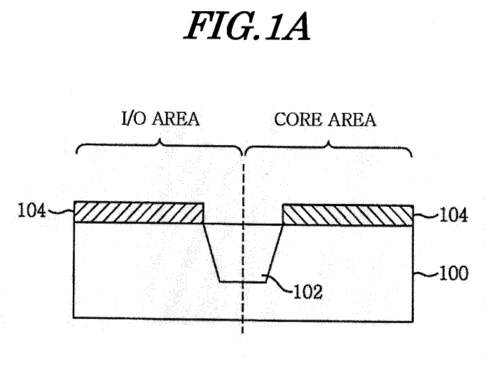

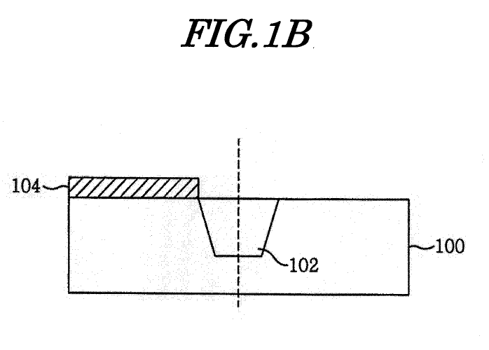

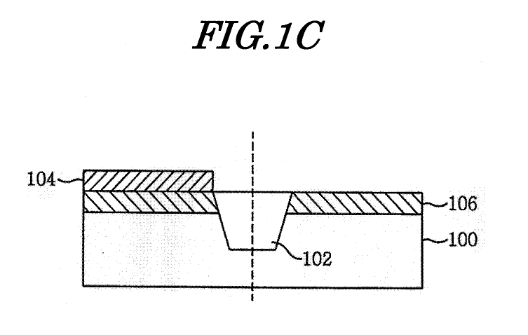

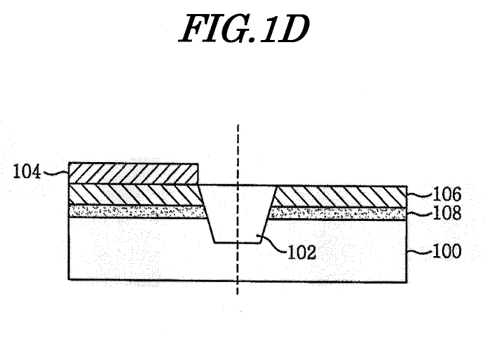

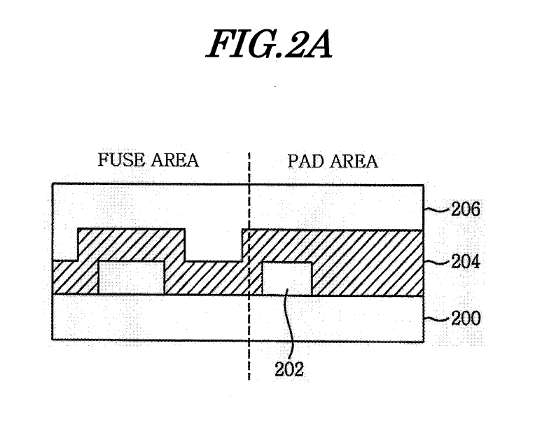

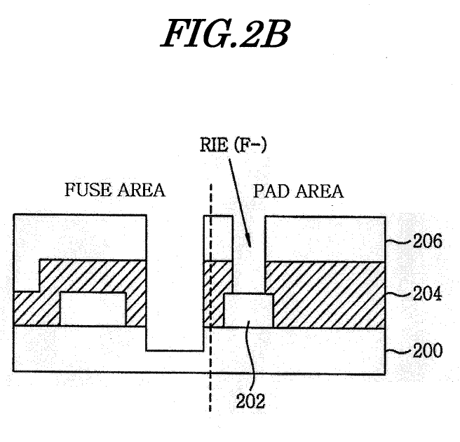

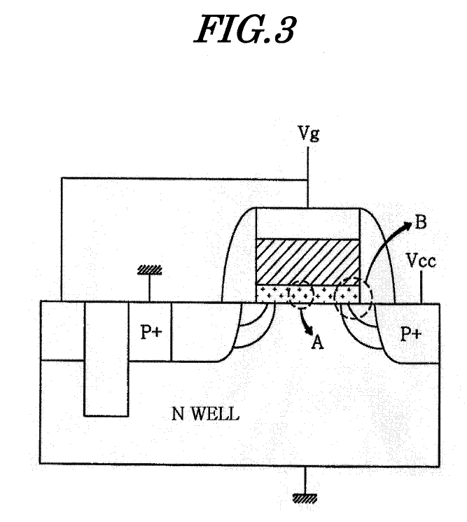

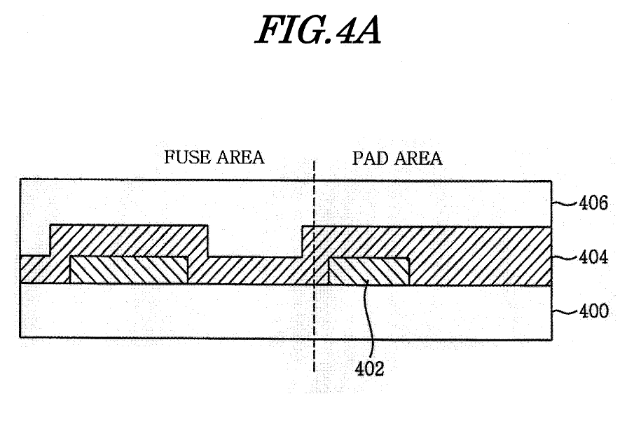

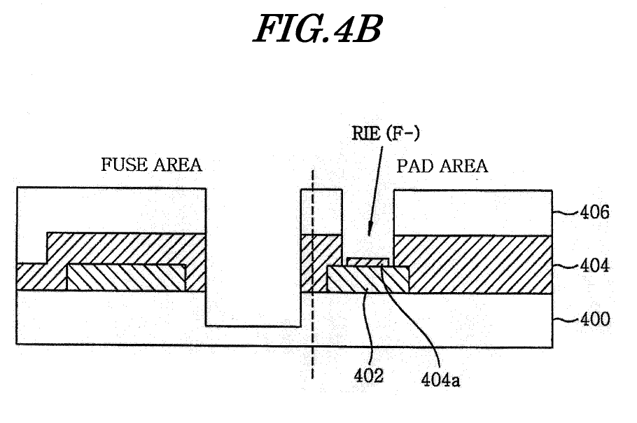

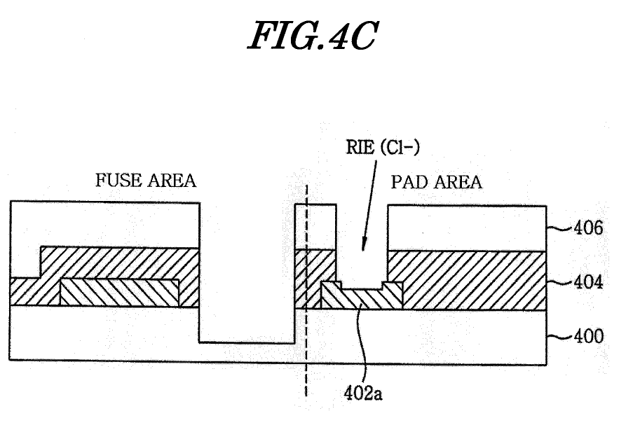

Example FIGS. 4A to 4C are sectional views showing a method for manufacturing a MOSFET of a semiconductor device according to embodiments.

### DETAILED DESCRIPTION

According to embodiments, when performing a pad exposure process of a pMOS transistor, an inter-layer dielectric layer is etched using a fluorine (F) gas. A TiN component remaining on the upper part of a metal interconnection is removed using chlorine (Cl) gas, thereby preventing degradation of the pMOS transistor.

FIGS. 4A to 4C are sectional views showing a process for manufacturing a MOSFET, particularly, a pad exposure process of a pMOS transistor according to embodiments.

As shown in FIGS. 4A to 4C, the logic structure of the pMOS transistor may be divided into a fuse area and a pad area.

As shown in FIG. 4A, after forming a metal interconnection 402 such as aluminum (Al) over an upper part of a semiconductor substrate 400, an inter-layer dielectric layer 404 may be formed by CVD. The inter-layer dielectric layer 404 may include a TEOS (tetraetylorthosilicate) layer. A protection layer 406 is deposited over the upper part of the inter-layer dielectric layer 404.

In FIG. 4B, an area defining a fuse and a pad is masked by photoresist and then dry-etched. The gas used for etching the inter-layer dielectric layer 404 includes a fluorine (F) component. The protection layer 406 and the inter-layer dielectric layer 404 of the pad area are primarily etched through the reaction between fluorine (F) and the inter-layer dielectric layer 404.

Although the pressure of an etching chamber is variable according to the type of equipment used, the pressure of the chamber is set as high as possible to prevent problems such as arcing and plasma extinction. The pressure of the chamber may be set to a value of about 100 mT or more.

The etching process is performed until the remaining oxide layer of the fuse area has a predetermined depth. As shown in FIG. 4B, a TiN component 404a may remain over the upper surface of the metal interconnection pad due to the etching selectivity of the dielectric layer over the TiN layer. Although TiN must be completely removed in order to prevent bonding defects when performing an assembly process, additional etching may cause the loss of an oxide material in the fuse area. Accordingly, the etching process using fluorine (F) gas is stopped in FIG. 4B.

According to embodiments, as shown in FIG. 4C, a second etching process is performed on the surface of the metal interconnection 402, using an etching gas including a chlorine (Cl) component. Thus, to prevent over-etching the fuse area, the etching environment is changed to use a chlorine (Cl) component mainly used for metal line etching. This can be achieved by transferring the semiconductor substrate 400 to a chamber capable of utilizing chlorine (Cl), depending on the configuration of gas feeds in the etching equipment.

As shown in FIG. 4C, an additional dry-etching process is performed by using the chlorine (Cl) gas. The chlorine (Cl) gas reacts with the metal interconnection of the pad area, that is, aluminum (AL), removing a portion of the surface. Reference number 402a designates a metal connection, the surface of which has been removed by the chlorine (Cl) gas.

The chlorine (Cl) gas etching step removes the surface of the metal interconnection 402 to a predetermined depth, for example, 1000 Å. According to embodiments, in the chlorine (Cl) gas etching step, the remaining TiN component 404a as well as the surface of the metal interconnection 402 is removed. The thickness of the inter-layer dielectric layer 404 is controlled to a predetermined depth due to high etching selectivity for the inter-layer dielectric layer 404 of the fuse area.

If the semiconductor substrate 400 is subject to the chlorine (Cl) gas etching step, additional impurities and/or chlorine (Cl) reactants, remain on the upper part of the metal interconnection 402a, causing pad corrosion. According to embodiments, a solvent is used to remove the residual chlorine (Cl) components and impurities.

In addition, a baking process is performed together with the solvent cleaning process in a nitride containing atmosphere. The nitride atmosphere may be an N₂ atmosphere in a temperature range of 300° C. to 400° C.

As described above, according to embodiments, when exposing a pad of a PMOS transistor, an inter-layer dielectric layer is primarily etched with a fluorine (F) gas, and then secondarily etched by using a chlorine (Cl) gas, thereby completely removing a TiN component on the upper part of the metal interconnection.

According to embodiments, in a semiconductor product including a PMOS transistor having a NO gate structure, when intense plasma inevitably occurs due to etching selectivity used for controlling the thickness of the inter-layer dielectric layer of a fuse area while removing TiN on the upper part of pad metal during a pad/fuse dry etching process, an etching gas is dualized into fluorine (F) and chlorine (Cl), thereby unconstraining process conditions such as chamber pressure, thereby preventing the degradation of the characteristics of the pMOS transistor. In addition, according to embodiments, it is possible to substantially reduce plasma damage during the BEOL dry etching process.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method of manufacturing a semiconductor device having a fuse area and a pad area, the method comprising:
depositing an inter-layer dielectric layer over a semiconductor substrate having a metal interconnection;
depositing a protection layer over the inter-layer dielectric layer;
using a photoresist mask to define areas to be etched in the fuse area and a pad area;
etching the protection layer and the inter-layer dielectric layer in the pad area and the fuse area, thereby exposing the metal interconnection in the pad area, and removing the dielectric material to a predetermined depth in a fuse area, using an etching gas including a first component; and
stopping the first etching process and performing a second etching process for selectively etching a surface of the metal interconnection using an etching gas including a second component.

2. The method as claimed in claim 1, wherein the first component comprises fluorine (F) gas.

3. The method as claimed in claim 1, wherein the second component comprises chlorine (Cl) gas.

4. The method as claimed in claim 1, wherein a pressure of a chamber for the first etching process is about 100 mT or more.

5. The method as claimed in claim 1, wherein the second etching process removes a remaining TiN component from the metal interconnection exposed through the first etching process.

6. The method as claimed in claim 1, wherein the second etching process removes the surface of the metal interconnection to a depth of about 1000 Å.

7. The method as claimed in claim 1, further comprising:
performing a solvent cleaning process after the second etching process; and
performing a baking process under a nitride atmosphere.

8. The method as claimed in claim 7, wherein the nitride atmosphere includes N₂ at a temperature in a range of 300° C. to 400° C.

9. The method as claimed in claim 1, wherein the inter-layer dielectric layer comprises a TEOS (tetraetylorthosilicate) layer.

10. A method comprising:
depositing an inter-layer dielectric layer over a semiconductor substrate having a metal interconnection;
depositing a protection layer over the inter-layer dielectric layer;
etching the protection layer and the inter-layer dielectric layer to expose the metal interconnection, and removing the protection layer and dielectric material to a predetermined depth in a fuse area, using an etching gas including a first component; and
selectively etching a surface of the metal interconnection using an etching gas including a second component.

11. The method as claimed in claim 10, wherein the first component comprises fluorine (F) gas.

12. The method as claimed in claim 10, wherein the second component comprises chlorine (Cl) gas.

13. The method as claimed in claim 10, wherein a pressure of a chamber for the etching process with the first component is about 100 mT or more.

14. The method as claimed in claim 10, wherein the etching process with the second component removes a remaining TiN component from the metal interconnection exposed through the etching process with the first component.

15. The method as claimed in claim 10, wherein the etching process with the second component removes the surface of the metal interconnection to a depth of about 1000 Å.

16. The method as claimed in claim 10, further comprising the sub-steps of:
performing a solvent cleaning process after the etching process with the second component; and
performing a baking process under a nitride atmosphere.

17. The method as claimed in claim 16, wherein the nitride atmosphere includes N₂ at a temperature in a range of 300° C. to 400° C.

18. The method as claimed in claim 10, wherein the inter-layer dielectric layer comprises a TEOS (tetraetylorthosilicate) layer.

19. The method as claimed in claim 10, further comprising using a photoresist mask to define areas to be etched in a fuse area and an interconnection pad area.
